(19) United States
(12) Patent Application Publication
(10) Pub. No.: US 2006/0038632 A1
(43) Pub. Date: Feb. 23, 2006

(54) Series-parallel resonant matching circuit and broadband amplifier thereof

(76) Inventors: Dow-Chih Niu, Taipei (TW); Hao-Jung Li, Taipei City (TW); Yuen-Shiang Huang, Jhongli City (TW)

Correspondence Address: J C PATENTS, INC., 4 VENTURE, SUITE 250, IRVINE, CA, 92618, US

(21) Appl. No.: 10/923,196

(22) Filed: Aug. 20, 2004

(51) Int. Cl. H03H 7/38

(52) U.S. Cl. 333/32

(57) ABSTRACT

A series-parallel resonant matching circuits and a broadband power amplifier thereof are disclosed. The series-parallel resonant matching circuit is connected to the last power transistor and the next power transistor. The series-parallel resonant matching circuit comprises a series matching inductor, a parallel matching inductor and an impedance transformation unit. The impedance transformation unit is connected between the series matching inductor and the intrinsic parallel matching inductor for transforming impedance. The parallel matching inductor and the parallel capacitor of a last level power transistor constitute a LC parallel resonant circuit, the series matching inductor and the series intrinsic capacitor of a next level power transistor constitute a LC series resonant circuit. Besides, the intrinsic parallel capacitance is a drain-to-source capacitor for the power transistor. The intrinsic series capacitance is a gate-to-source capacitor for the power transistor.

### BACKGROUND OF THE INVENTION

1. Field of the Invention

The present invention relates to a power amplifier, and more suitable for broadband power amplifier for broadband operations.

2. Description of the Related Art

Wireless communication systems have widely adopted power amplifiers for amplifying signals. In general, narrowband parallel resonant circuits and series resonant circuits have been applied for the design of the internal impedance matching circuits.

FIG. 1A is a schematic equivalent circuit showing a prior art parallel resonant circuit. In the prior art circuit, an inductor L_{P}, a capacitor C_{P} and a resistor R_{P} are parallel connected to each other so as to constitute a parallel network. FIG. 1B shows a Smith chart of the prior art parallel resonant circuit shown in FIG. 1A. FIG. 1C is a frequency response of the return loss S11 and the insertion loss S21.

Referring to FIG. 1B, the curve of FL, FC and FH represents the return loss S11 varying with frequency. The formula of the central frequency FC is shown below:

$$FC = \frac{FL + FH}{2} = \frac{1}{2 π \sqrt{LpCp}} = \frac{1}{2 π \sqrt{LsCs}} \qquad ( Formula 1 )$$

Referring to FIGS. 1B and 1C, when the frequency is lower than the central frequency FC, the inductor dominates the impedance; when the frequency is higher than the central frequency FC, the impedance is dominated by the capacitor. Only when the frequency is equal to the central frequency FC does the impedance have optimum conjugate match.

FIG. 2A is a schematic diagram showing a prior art series resonant circuit. In the prior art circuit, an inductor L_{P}, a capacitor C_{P} and a resistor R_{P} are series connected to each other so as to constitute a series network. FIG. 2B shows a Smith chart of the prior art series resonant circuit shown in FIG. 2A. FIG. 2C is a frequency response of the return loss S11 and the insertion loss S21.

Referring to FIG. 2B, the curve of FL, FC and FH represents the return loss S11 varying with frequency. The formula of the central frequency FC in FIG. 2B is similar to that shown in FIG. 11B as shown in Formula 1.

Referring to FIGS. 8B and 8C, when the frequency is lower than the central frequency FC, the impedance is dominated by the capacitor; when the frequency is higher than the central frequency FC, the inductor dominates the impedance. Only when the frequency is equal to the central frequency FC does the impedance have optimum conjugate match.

For high speed communication, the wireless communication systems required wide bandwidths. FIG. 3 is a schematic drawing showing a design of the bandwidth of LNA (Local area network, IEEE 802.11a). By the power amplifiers with the design of the narrowband resonant matching circuits, it is difficult to satisfy the requirement of the broadband power amplifier. The fluctuation of narrowband matching circuits caused by fabrication will greatly reduce the performance and the manufacture yield.

FIG. 4 is maximum power gain curves of a prior art power transistor. Referring to FIG. 4, when the working frequency of the power transistor is smaller than cut-off frequency FC of current gain, the maximum power gain decays by 3 dB/octave. When the operational frequency of the power transistor is higher than the cut-off frequency FC, the maximum power gain decays by 6 dB/octave. A two-stage power amplifier work between 4 GHz-8 GHz, without impedance match, the difference between the maximum gain of the lowest frequency and the highest frequency is about 6 dB. Even if the narrowband impedance matching circuit is applied, the flatness of the power gain is still not acceptable.

### SUMMARY OF THE INVENTION

Accordingly, the present invention is directed to a broadband power amplifier having a series-parallel resonant matching circuit for broadband operations. The yield of the broadband power amplifier is improved.

The present invention discloses a series-parallel resonant matching circuit. The series-parallel resonant matching circuit is connected to the last power transistor and the next power transistor. The series-parallel resonant matching circuit comprises a series matching inductor, a parallel matching inductor and an impedance transformation unit. The impedance transformation unit is connected between the series matching inductor and the parallel matching inductor for transforming impedance. The parallel matching inductor of each series-parallel resonant matching circuit and the intrinsic parallel capacitor (drain to source capacitor, Cgs) of a last level power transistor constitute a LC parallel resonant circuit, the intrinsic series matching inductor of each series-parallel resonant matching circuit and the series capacitor (gate to source capacitor, Cgs) of a next level power transistor constitute a LC series resonant circuit.

In the embodiment of the present invention, the first parallel capacitor is a drain-to-source capacitor for the power transistor. The first series capacitor is a gate-to-source capacitor for the power transistor.

The present invention also discloses a broadband power amplifier. The broadband power amplifier comprises N-stage power transistors and N−1 series-parallel resonant matching circuits. Each of the transistors has a intrinsic series capacitor and a intrinsic parallel capacitor, Cds. Each of the series-parallel resonant matching circuits has a series matching inductor and a parallel matching inductor. The series-parallel resonant matching circuits are alternatively connected to the power transistors. The parallel matching inductor of each series-parallel resonant matching circuit and the intrinsic parallel capacitor (drain to source capacitor, Cgs) of a last level power transistor constitute a LC parallel resonant circuit, the series matching inductor of each series-parallel resonant matching circuit and the s intrinsic series capacitor (gate to source capacitor, Cgs)r of a next level power transistor constitute a LC series resonant circuit, and N is a positive integral number larger than or equal to 1.

In the embodiment of the present invention, each of the series-parallel resonant matching circuits further comprises an impedance transformation unit. The impedance transformation unit is disposed between the parallel matching inductor and the series matching inductor for transforming impedance.

The present invention uses the series-parallel resonant matching circuit for a power amplifier. Accordingly, the power amplifier executes broadband operations, and the yield of the broadband power amplifier is improved.

The above and other features of the present invention will be better understood from the following detailed description of the preferred embodiments of the invention that is provided in communication with the accompanying drawings.

### BRIEF DESCRIPTION OF THE DRAWINGS

FIG. 1A is a schematic diagram circuit showing a prior art parallel resonant circuit.

FIG. 1B shows a Smith chart of the prior art parallel resonant circuit shown in FIG. 1A.

FIG. 1C is a frequency response of the return loss S11 and the insertion loss S21.

FIG. 2A is a schematic diagram showing a prior art series resonant circuit.

FIG. 2B shows a Smith chart of the prior art series resonant circuit shown in FIG. 2A.

FIG. 2C is a frequency response of the return loss S11 and the insertion loss S21.

FIG. 3 is a schematic diagram showing a design of the bandwidth of LAN (Local Area Network).

FIG. 4 is maximum power gain curves of a prior art power transistor.

FIG. 5A is a schematic diagram showing an equivalent circuit of series-parallel resonant matching circuits according to an embodiment of the present invention.

FIG. 5B shows a Smith chart of series-parallel resonant matching circuits according to an embodiment of the present invention.

FIG. 5C shows a frequency response of the return loss S11 and the insertion loss S21 according to an embodiment of the present invention.

FIG. 6 is a schematic block diagram showing an N-stage broadband power amplifier according to an embodiment of the present invention.

FIG. 7 is a schematic diagram showing a two-stage broadband power amplifier according to an embodiment of the present invention.

FIG. 8 is a Smith chart of series-parallel resonant matching circuit according to an embodiment of the present invention.

FIG. 9 is a Smith chart of a series resonant matching circuit according to this embodiment of the present invention.

FIG. 10 is the measured results of a broadband MMIC power amplifier according to an embodiment of the present invention.

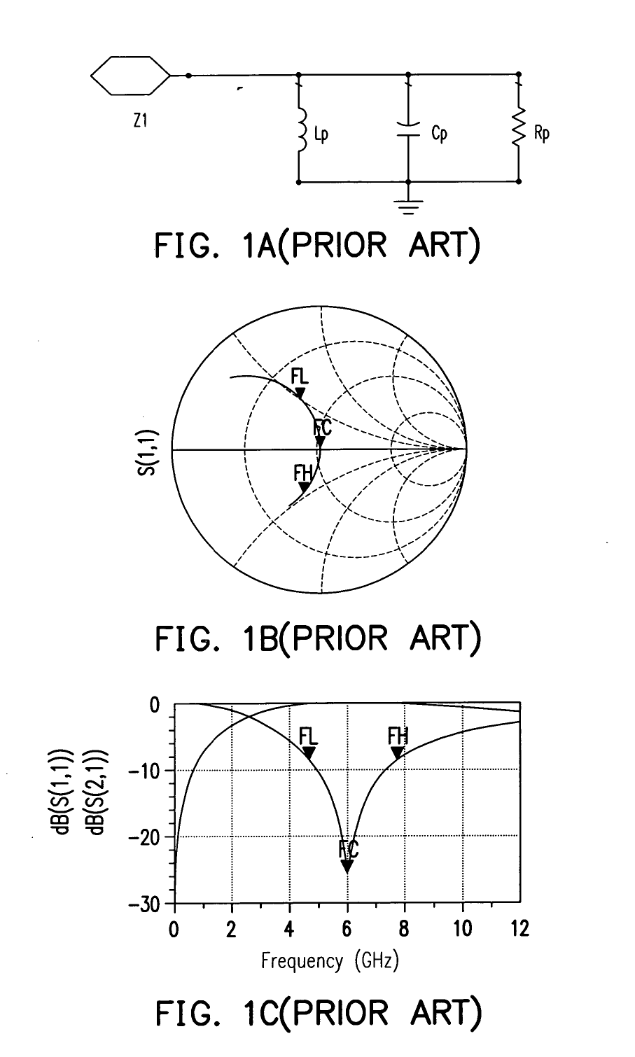

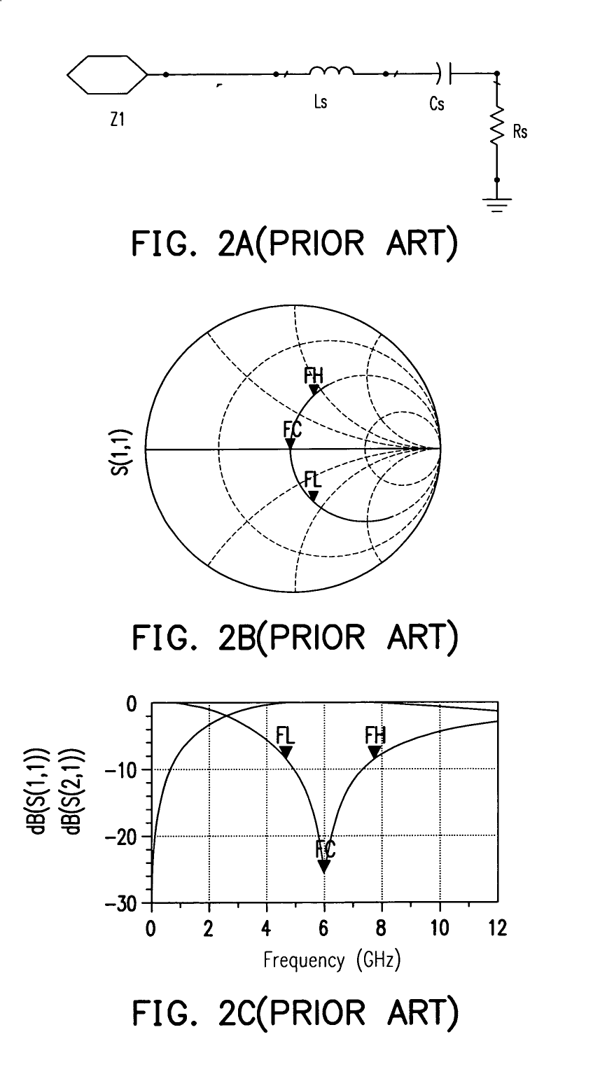

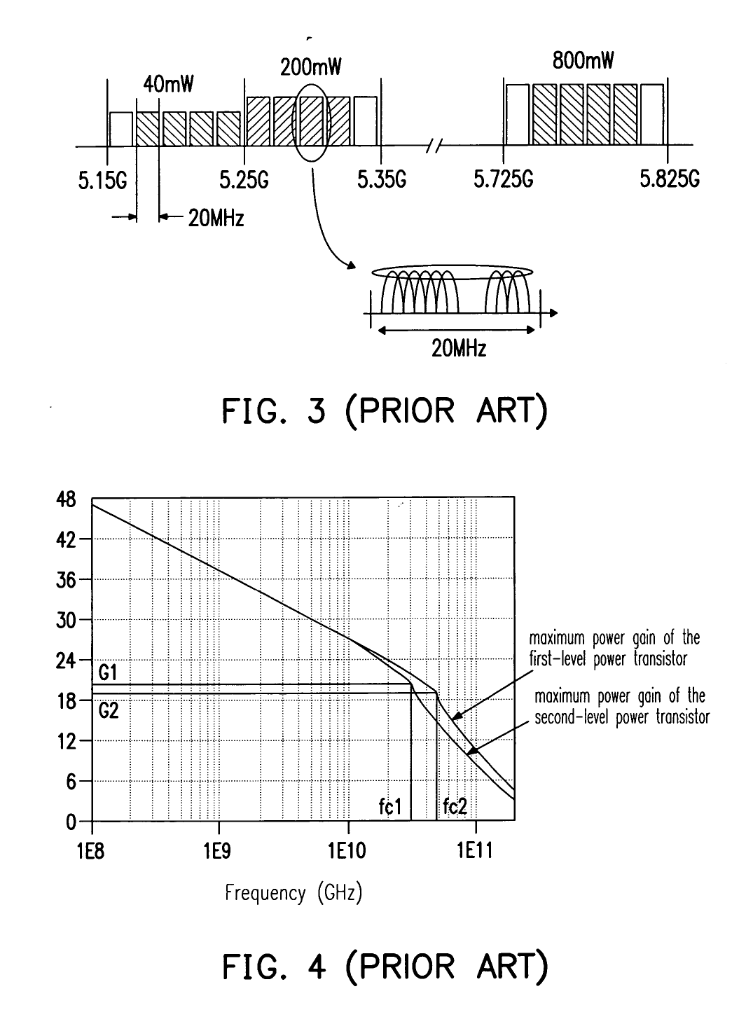

### DESCRIPTION OF SOME EMBODIMENTS

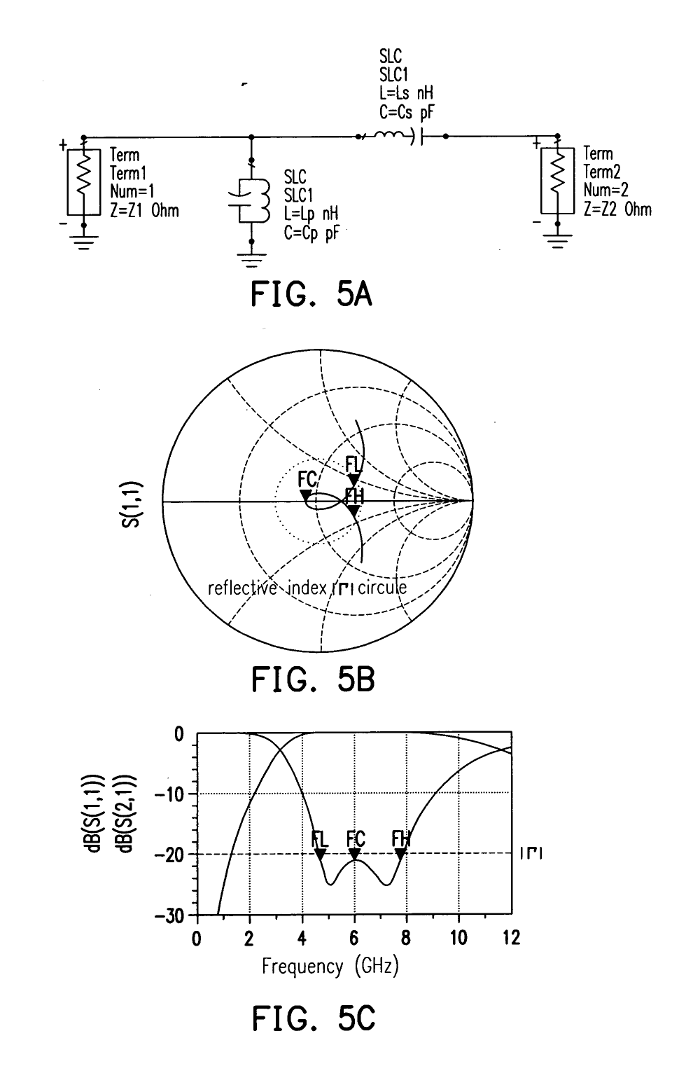

FIG. 5A is a schematic diagram showing an equivalent circuit of series-parallel resonant matching circuits according to an embodiment of the present invention. In this embodiment, one of ordinary skill in the art will design L_{P}, C_{P}, L_{S} and C_{S} so as to determine bandwidth and create the frequency response. The matching circuit is similar to a two-order band-pass filter. Referring to FIGS. 5B and 5C, when the frequency is lower than the central frequency FC, the impendence is contributed mainly from the capacitor. In contrast, when the frequency is higher than the central frequency FC, the impendence is contributed mainly from the inductor. Accordingly, in the bandwidth from FL to FH, the return loss S11 converges in the circle of the reflection coefficient |Γ| of the Smith chart, wherein S21 represents the insertion loss.

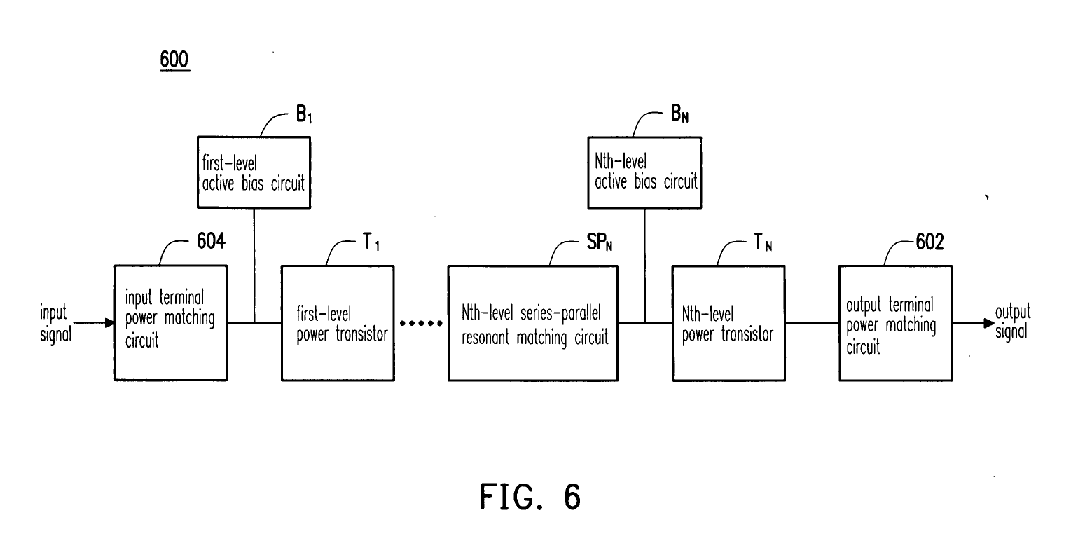

FIG. 6 is a schematic block diagram showing an N-stage broadband power amplifier according to an embodiment of the present invention. The N-stage broadband power amplifier 600 comprises a input terminal matching circuit 604, N−1 series-parallel resonant matching circuits, N power transistors, an output terminal power matching circuit and N active bias circuits, wherein N is a positive integral number larger than or equal to 1.

In this embodiment, the input terminal of the input terminal matching circuit 604 serves as the input terminal of the N-stage broadband power amplifier 600 for receiving an input signal. The input terminal of the first-stage power transistor T₁ is connected to the output terminal of the input terminal matching circuit 604. The output terminal of the first-stage power transistor T₁ is connected to the second-stage series-parallel resonant matching circuit SP₂. According to the arrangement described above, the series-parallel resonant matching circuits SP₂-SP_{N} and the power transistors T₁-T_{N} are connected to each other alternatively. The output terminal of the Nth-stage power transistor T_{N} is connected to the output terminal of the output terminal power matching circuit 602 for outputting an output signal.

In this embodiment, the first-stage active bias circuit B₁ supplies an active bias to the input terminal matching circuit 604 and the first-stage power transistor T₁. Accordingly, each of the of the active bias circuits B₁-B_{N} can, for example, supply active biases to the corresponding series-parallel resonant matching circuits and the power transistors. The present invention, however, is not limited thereto.

In the preferred embodiment of the present invention, the power level of the broadband power amplifier 600 depends on the design of the circuit.

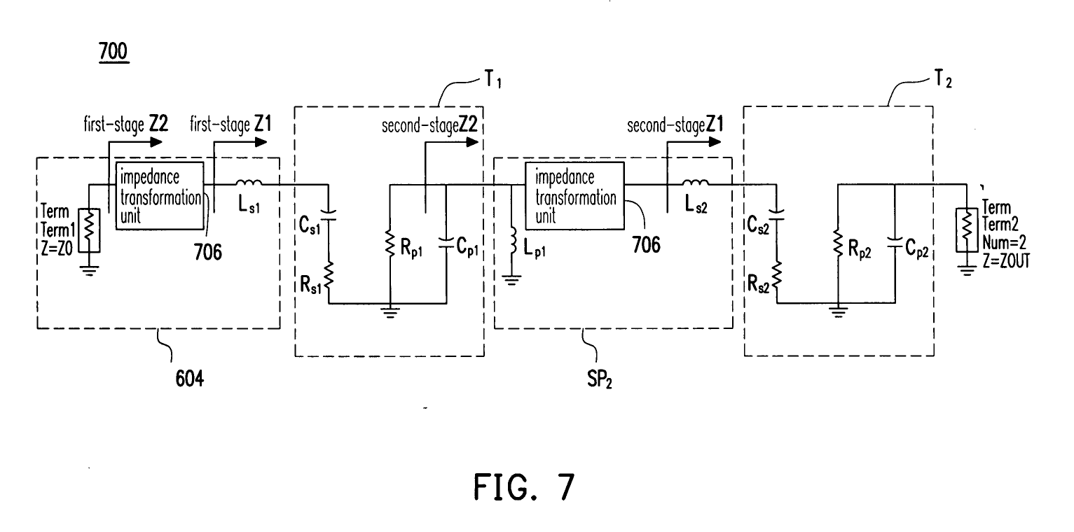

FIG. 7 is a schematic drawing showing a second-stage broadband power amplifier according to an embodiment of the present invention. The present invention is not limited thereto.

Referring to FIG. 7, the input terminals of the power transistors T₁ and T₂ can be represented by RC series circuits, and the output terminals of the power transistors T₁ and T₂ can be represented by RC parallel circuits.

In the second-stage series-parallel resonant matching circuit SP₂, the drain-to-source parallel capacitor C_{S2} of the first-stage power transistor T₁ and the matching inductor L_{P1} connected to a ground terminal constitute a LC parallel resonant circuit. The capacitor C_{P2} of the second-stage power transistor T₂ and the matching inductor L_{S2} constitute a LC series resonant circuit. Because the resistor R_{S2} is smaller than the resistor R_{P1}, an impedance transformation unit 706 has to be added between the LC parallel resonant circuit and the LC series resonant circuit so as to transform impedance. The inductor Lp1 also work as a D.C. grounded chock.

In the input terminal matching circuit 604, the source-to-gate capacitor C_{S1} of the first-stage power transistor T₁ and the matching inductor L_{S1} constitute a LC series resonant circuit. Because the series resistor R_{S2} is smaller than Z0, an impedance transformation unit 706 has to be added between the LC series resonant circuit and the input terminal of the series-parallel resonant matching circuits so as to transform impedance.

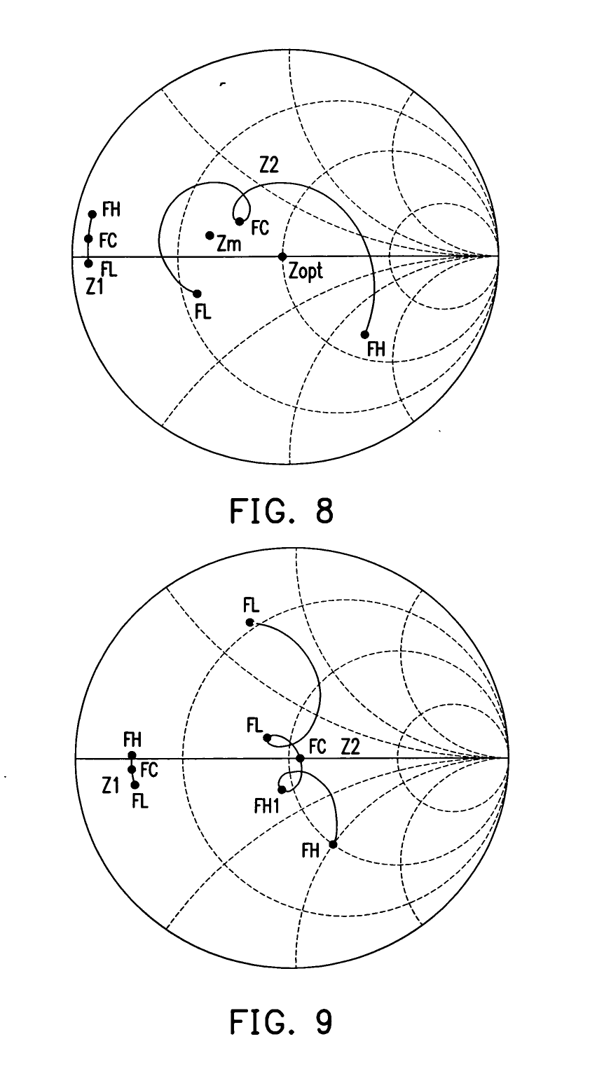

FIG. 8 is a Smith chart to show the result after putting series parallel resonant matching circuit according to an embodiment of the present invention. All impedances are normalized to system impendence Zₘ represents the impedance for optimum gain at the central frequency. As shown in FIGS. 6 and 8, the series parallel resonant matching circuit SP₂ matches the first-stage output impedance Z₁ to the second-stage impedance Z₂. During the bandwidth between FL and FH, the impedance curve of the second-stage impedance Z₂ circles around Zₒₚₜ and Zₘ.

FIG. 9 is a Smith chart to show the result after putting the input terminal matching circuit 604 according to this embodiment of the present invention. All impedances are also normalized to the system impedance Z0. Referring to FIGS. 6 and 9, the input terminal matching circuit 604 matches the impedance Z₁ at the input terminal to the impedance Z₂. During the bandwidth FL and FH, the impedance curve of the impedance Z₂ results in two circles near to the impedance Z0.

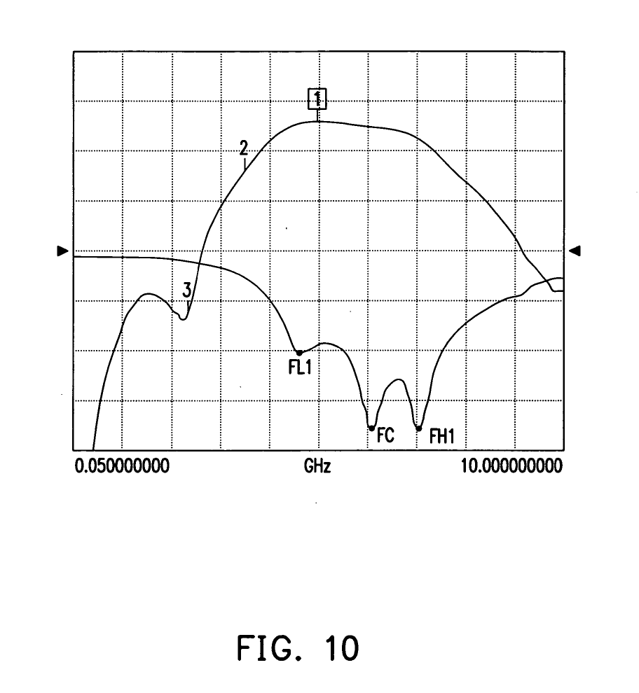

FIG. 10 is the measured result of a broadband MMIC power amplifier according to an embodiment of the present invention. In this embodiment, the measurement shows the gain and input return loss of the broadband MMIC power amplifier. According to curves in FIG. 10, the broadband power amplifier obtains a quit good gain and return loss with large bandwidth.

Therefore, the broadband power amplifier combines series resonant matching circuits and parallel resonant matching circuits so as to form series-parallel resonant matching circuits. The bandwidth of the broadband power amplifier can be matched by series-parallel resonator as to obtain desired performances.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A series-parallel resonant matching circuit, comprising:
a series matching inductor;
a parallel matching inductor; and
an impedance transformation unit connected between the series matching inductor and the parallel matching inductor for transforming impedance.

2. The series-parallel resonant matching circuit of claim 1, wherein the series-parallel resonant matching circuit comprises an input terminal and an output terminal, the input terminal is connected to a first-stage power transistor, and the output terminal is connected to a second-stage power transistor.

3. The series-parallel resonant matching circuit of claim 2, wherein the first-stage power transistor comprises a first intrinsic parallel capacitor, and the first intrinsic parallel capacitor and the parallel matching inductor constitutes a LC parallel resonant circuit.

4. The series-parallel resonant matching circuit of claim 3, wherein the first parallel capacitor is a drain-to-source capacitor for the first-stage power transistor.

5. The series-parallel resonant matching circuit of claim 4, wherein the second-stage power transistor comprises a second intrinsic series capacitor, and the second intrinsic series capacitor and the series matching inductor constitute a LC series resonant circuit.

6. The series-parallel resonant matching circuit of claim 5, wherein the second series capacitor is a gate-to-source capacitor for the second-stage power transistor.

7. The series-parallel resonant matching circuit of claim 1 adapted for a multi-stage microwave power amplifier.

8. A broadband power amplifier, comprising:
N-stage power transistors, each of the transistors comprising a series capacitor and a parallel capacitor; and
N−1 series-parallel resonant matching circuits, each of the series-parallel resonant matching circuits having a series matching inductor and a parallel matching inductor, the series-parallel resonant matching circuits alternatively connected to the power transistors, wherein the parallel matching inductor of each series-parallel resonant matching circuit and the intrinsic parallel capacitor (drain to source capacitor) of a last level power transistor constitute a LC parallel resonant circuit, the series matching inductor of each series-parallel resonant matching circuit and the series intrinsic capacitor (gate to source capacitor) of a next level power transistor constitute a LC series resonant circuit, and N is a positive integral number larger than or equal to 1.

9. The broadband power amplifier of claim 8, wherein each of the series-parallel resonant matching circuits further comprises an impedance transformation unit, the impedance transformation unit is disposed between the parallel matching inductor and the series matching inductor for transforming impedance.
